(19) United States
(12) Patent Application Publication
(10) Pub. No.: US 2025/0085635 A1
(43) Pub. Date: Mar. 13, 2025

(54) DEVELOPABLE RESIST OVERLAYER COMPOSITION AS WELL AS METHOD FOR MANUFACTURING RESIST OVERLAYER PATTERN AND RESIST PATTERN

(71) Applicant: Merck Patent GMBH, Darmstadt (DE)

(72) Inventors: Hiroshi Yanagita, Kakegawa (JP); Kazuma Yamamoto, Kakegawa (JP)

(21) Appl. No.: 18/961,252

(22) Filed: Nov. 26, 2024

Related U.S. Application Data
(63) Continuation of application No. PCT/EP2023/063711, filed on May 23, 2023.

(30) Foreign Application Priority Data
May 26, 2022 (JP) 2022-86130

(51) Int. Cl. G03F 7/09; C09D 167/04; H01L 21/027

(52) U.S. Cl. CPC G03F 7/094; C09D 167/04; H01L 21/0274

(57) ABSTRACT

A developable resist overlayer composition as well as a method for manufacturing a resist overlayer pattern and a resist pattern are provided.

### CROSS REFERENCE TO RELATED APPLICATIONS

This application is a Continuation under 35 USC § 111 (a) of International Patent Application No. PCT/EP2023/063711, filed May 23, 2023, which claims benefit of Japanese Application No. 2022-86130, filed May 26, 2022. The contents of these applications are incorporated herein by reference in their entirety.

### BACKGROUND OF THE INVENTION

### Technical Field

The present invention relates to a developable resist overlayer composition as well as a method for manufacturing a resist overlayer pattern and a resist pattern.

### Background Art

In recent years there has been an increased need for high integration of LSI, and miniaturization of resist patterns is also required. In order to respond such needs, lithography processes using short wavelength such as KrF excimer laser, ArF excimer laser, extreme ultraviolet and X-ray, electron beam or the like have been put into practical use.

In order to obtain a finer pattern, there is a method for making the hole diameter or separation width finer by covering a resist pattern formed within a range that can be stably obtained by a conventional method with a composition containing a polymer, thereby thickening the resist pattern. This is mainly aimed at increasing the width of the resist pattern, and this is that after the resist pattern is once developed, a composition containing a polymer is further applied.

A resist overlayer composition, which makes it possible to allow only EUV or electron beam to selectively pass through and to block outgassing from the resist, has been proposed, as disclosed in WO 2016/013598, WO 2014/115843, and WO 2015/129486. These compositions are those to be applied before exposure, and increasing the film thickness of the resist is not disclosed.

### SUMMARY OF THE INVENTION

### Problems to be Solved by the Invention

The present inventors considered that there are one or more problems with the method for manufacturing a resist pattern still need improvements. They include, for example, the following: thickening a fine resist pattern; obtaining a fine resist pattern useful as an etching mask; obtaining sufficient resolution even when using an exposure apparatus with an increased numerical aperture; obtaining a fine pattern having a good shape; obtaining a resist pattern with a high aspect ratio; widening a process window; the overlayer itself can be developed and patterned; thickness of the resist film is not substantially reduced when a resist overlayer composition is applied; a resist overlayer can be formed on a resist film; a resist overlayer composition can be applied on a resist film after exposure; a resist overlayer composition can be applied on a resist film before development; a resist overlayer can accept an acid from a resist film; solubility of the resist overlayer can be changed by an acid accepted from a resist film; a resist overlayer does not almost need to contain components that generate strong acid; an acid with a long diffusion distance can be generated by ion exchange with the acid accepted from a resist film; and manufacturing yield is improved.

THE PRESENT INVENTORS CONSIDERED AND STUDIED AS FOLLOWS:

DOF (Depth of Focus) refers to the range of depth of focus in which a resist pattern can be formed with a dimension in which the deviation from the target dimension is within a predetermined range when exposure is performed with the focus shifted vertically at the same exposure dose.

The DOF is represented by the following formula:

$$k 2 \times λ / {NA}^{2}$$

where
   k2 is a constant, λ is the exposure wavelength, and NA is the numerical aperture.

The larger the DOF, the wider the process window, which is preferable. However, in high-precision lithography technology for IC and the like, there is a tendency that the NA of exposure apparatus increases in the future, and it is expected that the DOF increasingly becomes narrower.

With EUV exposure, which is expected to be a high-definition technology, the formation of fine patterns with thin films has been achieved. The present inventors thought that it would be suitable to increase the thickness of resist pattern in order to make the resist pattern more durable when using the high-definition pattern as a mask in a later step. If the resist pattern is thin, for example, when it is used as an etching mask, the durability as a mask cannot be accomplished, and even the target to be masked may be etched in the final stage of the etching process.

When the thickness of resist film is thick, the process window tends to become narrower. For example, if the focus fluctuates due to a slight fluctuation in the thickness of substrate, the shape of the formed resist pattern changes and becomes far from a rectangle, and there is possibility that pattern collapse or the like causes. In another example, if the exposure dose (Dose) fluctuates, it causes fluctuation of the line width, and there is possibility that pattern bridge or pattern collapse occurs. In high-definition technology that requires high resolution, thinner resist film can be adopted more easily.

The present invention has been made based on the technical background as described above and provides a developable resist overlayer composition capable of achieving thickening the resist pattern as well as a method for manufacturing a resist overlayer pattern and a resist pattern.

### Means for Solving the Problems

The developable resist overlayer composition according to the present invention comprises a hydrocarbon compound (A) and a solvent (B),
wherein,
the hydrocarbon compound (A) is a compound represented by the formula (0) or a polymer comprising a structure derived from the compound represented by the formula (0) as a repeating unit; and the solvent (B) comprises a solvent (B1) represented by the formula (b1):

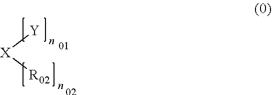

where
X is a C₁₋₆₀ hydrocarbon group;
n₀₁ is a number of 1 to 10, n₀₂ is a number of 0 to 10;
Y is a group represented by the formula (1) or —OH, provided that 40 to 100% of the total number of Y is a group represented by the formula (1);
R₀₂ is C₁₋₆ alkoxy (excluding t-butoxy), —(C═O)—R₀₃, —(C═O)—O—R₀₄, —(C═O)—N(R₀₅)₂, —O—(C═O)—R₀₆ or —NR₀₇—(C═O)—R₀₈;
R₀₃ is H or C₁₋₄ alkyl;
R₀₄ is C₁₋₄ alkyl (excluding t-butyl);
R₀₅ is each independently H or C₁₋₄ alkyl, and two R₀₅ can be bonded each other to form a ring structure;
R₀₆ is H, C₁₋₄ alkyl or C₁₋₄ alkoxy (excluding t-butoxy);
R₀₇ is H or C₁₋₄ alkyl;
R₀₈ is H, C₁₋₄ alkyl or —N(R₀₉)₂;
R₀₇ and R₀₈ can be bonded each other to form a ring structure when they are alkyl; and
R₀₉ is each independently H or C₁₋₄ alkyl, and two Rog can be bonded each other to form a ring structure,

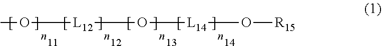

where
n₁₁, n₁₂, n₁₃ and n₁₄ are each independently a number of 0 to 1;
L₁₂ is selected from the group consisting of —C(═O)—, —CH₂—C(═O)—, —C(═O)—CH₂— and —CH(CH₃)—;
L₁₄ is C₁₋₅ alkylene;
R₁₅ is C₁₋₁₅ alkyl or C₂₋₇ alkenyl; and
the methyl of L₁₂ and the methyl of R₁₅ can be bonded each other to form a ring structure, and

R₂₁—O—R₂₂ (b1)
where
R₂₁ and R₂₂ are each independently C₁₋₈ alkyl.

The method for manufacturing a resist overlayer pattern and a resist pattern according to the present invention comprises the following steps:
(1) applying a resist composition above a substrate and heating the resist composition to form a resist film;
(2) optionally exposing the resist film;
(3) applying a developable resist overlayer composition directly on the resist film and heating the resist overlayer composition to form a resist overlayer;
(4) optionally exposing the resist film and the resist overlayer, provided that at least one of the exposures of (2) and (4) is performed;
(5) transferring the acid in the resist film to the resist overlayer; and
(6) developing the resist overlayer and the resist film using a developer to form a resist overlayer pattern and a resist pattern.

The method for manufacturing a device according to the present invention comprises the above-described method.

### Effects of the Invention

According to the invention, one or more of the following effects can be desired.

Thickening a fine resist pattern; obtaining a fine resist pattern useful as an etching mask; obtaining sufficient resolution even when using an exposure apparatus with an increased numerical aperture; obtaining a fine pattern having a good shape; obtaining a resist pattern with a high aspect ratio; widening a process window; the overlayer itself can be developed and patterned; thickness of the resist film is not substantially reduced when a resist overlayer composition is applied; a resist overlayer can be formed on a resist film; a resist overlayer composition can be applied on a resist film after exposure; a resist overlayer composition can be applied on a resist film before development; a resist overlayer can accept an acid from a resist film; solubility of the resist overlayer can be changed by an acid accepted from a resist film; a resist overlayer does not almost need to contain components that generate strong acid; an acid with a long diffusion distance can be generated by ion exchange with the acid accepted from a resist film; and manufacturing yield is improved.

### BRIEF DESCRIPTION OF THE DRAWING

FIG. 1 is a schematic view showing one embodiment of the method for manufacturing a resist overlayer pattern and a resist pattern.

### DETAILED DESCRIPTION OF THE INVENTION

### Mode for Carrying Out the Invention

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (B) or another component.

Hereinafter, embodiments of the present invention are described in detail.

### Developable Resist Overlayer Composition

The developable resist overlayer composition (hereinafter referred to as the composition) according to the present invention comprises a hydrocarbon compound (A) and a solvent (B), wherein the hydrocarbon compound (A) is a compound represented by the formula (0) or a polymer comprising a structure derived from the compound represented by the formula (0) as a repeating unit, and the solvent (B) comprises a solvent (B1) represented by the formula (b1).

The composition according to the present invention is a composition that forms a film on a resist film (preferably a composition that forms a film on a resist film after exposure; more preferably a composition that forms a film on a resist film after EUV exposure). In a preferred embodiment, the resist film is a positive type EUV resist film formed from a positive type EUV resist composition.

The resist overlayer formed on a resist film using the composition according to the present invention can be developed with a developer. A pattern derived from the composition according to the present invention (resist overlayer pattern) is formed on the resist pattern after development. In this way, application of the composition according to the present invention results in thickening the film of resist pattern.

The composition according to the present invention is not applied between resist patterns after development. However, the “development” in “after development” herein mentioned does not include the development that had been performed to pattern of the resist layer that was already removed. For example, in the case of a design in which resist patterning is performed several times in succession, it is possible to use the composition according to the present invention to thicken the resist layer in a later step after developing the resist in the previous step.

### (A) Hydrocarbon Compound

The composition according to the present invention comprises a hydrocarbon compound (A) (hereinafter referred to as the component (A); the same applies also to other components).

The hydrocarbon compound (A) is a compound represented by the formula (0) or a polymer comprising a structure derived from the compound represented by the formula (0) as a repeating unit. It is also a preferred embodiment of the present invention that the hydrocarbon compound (A) contains both the compound represented by the formula (0) and the polymer comprising a structure derived from the compound represented by the formula (0) as a repeating unit.

The formula (0) is as follows:

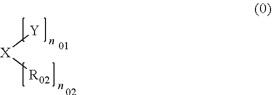

where
   X is a C₁₋₆₀ hydrocarbon group. X is preferably a group consisting of a combination of C₅₋₁₀ aryl and linear or branched C₁₋₆ alkyl, a group consisting of a combination of C₅₋₁₀ aryl and cyclic C₅₋₆ alkyl, a group consisting of cyclic C₅₋₁₀ alkyl, a group consisting of a combination of linear or branched C₁₋₆ alkyl and cyclic C₅₋₆ alkyl, or a group consisting of linear or branched C₁₋₆ alkyl (more preferably a group consisting of a combination of phenyl and branched C₁₋₆ alkyl, a group consisting of a combination of phenyl and cyclohexyl, a group consisting of cyclic C₅₋₆ alkyl, a group consisting of a combination of methyl and cyclohexyl, a group consisting of a combination of methyl and cyclopentyl, or a group consisting of a combination of linear C₁₋₆ alkyl; further preferably a group consisting of a combination of phenyl and branched C₂₋₃ alkyl, cyclohexyl, or a group consisting of linear C₃₋₅ alkyl). Although describing for clarity, H in the C₁₋₆₀ hydrocarbon group of X is bonded with Y by being substituted. The same is applied also to R₀₂.

The elements that constitutes X can be read as a linker depending on the number of other groups which are bonded to it. Details are given below. The following compounds can be read by the formula (0). X consists of three phenyl and C₂ alkyl. C₂ alkyl is read as a linker connecting three phenyl. n₀₂ is zero. n₀₁ is 3; 100% of the total number of Y are groups represented by the formula (1), and there are no Y that are —OH. In all Y, n₁₁ and n₁₂ are 1, n₁₃ and n₁₄ are 0, L₁₂ is —CH₂—C(═O)—, and R₁₅ is t-butyl.

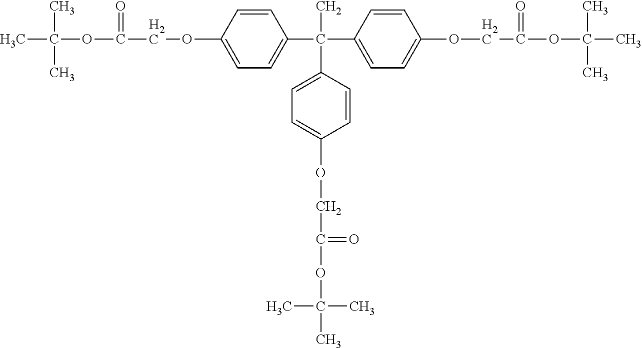 [SMILES: CC(C)(C)OC(=O)COc1ccc(C(C)(c2ccc(OCC(=O)OC(C)(C)C)cc2)c2ccc(OCC(=O)OC(C)(C)C)cc2)cc1]

n₀₁ is a number of 1 to 10 (preferably a number of 1 to 5; more preferably a number of 1 to 3; further preferably 1, 2 or 3).
n₀₂ is a number of 0 to 10 (preferably a number of 0 to 3; more preferably a number of 0 to 1; further preferably 0 or 1; further more preferably 0).
Y is a group represented by the formula (1) or —OH, provided that 40 to 100% (preferably 45 to 100%; more preferably 75 to 100%; further preferably 100%) of the total number of Y is a group represented by the formula (1). It is preferable to calculate the “total number of Y” by molar ratio. R₀₂ is C₁₋₆ alkoxy (excluding t-butoxy), —(C═O)—R₀₃, —(C═O)—O—R₀₄, —(C═O)—N(R₀₅)₂, —O—(C═O)—R₀₆ or —NR₀₇—(C═O)—R₀₈.

Although not to be bound by theory, modifications that do not interfere with the reaction of the group represented by the formula (1) can be R₀₂. These groups are preferred rather than any functional group of strong acid such as carboxylic or sulfonic acid, or basic functional group. R₀₂ is preferably C₁₋₆ alkoxy (further more preferably methoxy).
R₀₃ is H or C₁₋₄ alkyl (preferably H, methyl, ethyl, isopropyl, n-propyl, n-butyl or t-butyl; more preferably H, methyl, n-propyl or n-butyl; further preferably H or methyl).
R₀₄ is C₁₋₄ alkyl (excluding t-butyl). R₀₄ is preferably H, methyl, ethyl, isopropyl, n-propyl or n-butyl (more preferably H, methyl, n-propyl or n-butyl; further preferably H or methyl).
R₀₅ is each independently H or C₁₋₄ alkyl, and two R₀₅ can be bonded each other to form a ring structure. R₀₅ is each independently, preferably H, methyl, ethyl, isopropyl, n-propyl, n-butyl or t-butyl (more preferably H, methyl, n-propyl or n-butyl; further preferably H or methyl).

The following compound can be read by the formula (0). X consists of three phenyl and C₂ alkyl. n₀₁ is 2. 100% of the total number of Y are groups represented by the formula (1). In one group of the formula (1), n₁₁ and n₁₂ are 1, n₁₃ and n₁₄ are 0, L₁₂ is —CH₂—C(═O)—, and R₁₅ is t-butyl. In the other group of the formula (1), n₁₁, n₁₂, n₁₃ and n₁₄ are 0 and R₁₅ is vinyl (C₂ alkenyl). n₀₂ is 1. R₀₂ is —(C═O)—N(R₀₅)₂. R₀₅ is C₂ alkyl and C₃ alkyl, forming a ring structure.

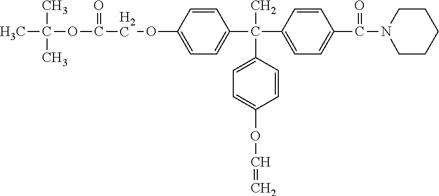 [SMILES: C=COc1ccc(C(C)(c2ccc(OCC(=O)OC(C)(C)C)cc2)c2ccc(C(=O)N3CCCCC3)cc2)cc1]

R₀₆ is H, C₁₋₄ alkyl or C₁₋₄ alkoxy (excluding t-butoxy) (preferably H, methyl, ethyl, isopropyl, n-propyl, n-butyl, t-butyl or methoxy; more preferably H, methyl, n-propyl, n-butyl or methoxy).
R₀₇ is H or C₁₋₄ alkyl (preferably H, methyl, ethyl, isopropyl, n-propyl, n-butyl or t-butyl; more preferably H, methyl, n-propyl or n-butyl).
R₀₈ is H, C₁₋₄ alkyl or —N(R₀₉)₂, and R₀₇ and R₀₈ can be bonded each other to form a ring structure when they are alkyl; and
R₀₉ is each independently H or C₁₋₄ alkyl, and two R₀₉ can be bonded each other to form a ring structure.
R₀₈ is preferably H, methyl, t-butyl or —N(R₀₉)₂.
R₀₉ is preferably H, methyl, ethyl, isopropyl, n-propyl, n-butyl, t-butyl or methoxy (more preferably H, methyl, n-propyl, n-butyl or methoxy).

The formula (1) is as follows:

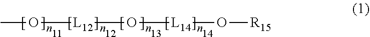

where
   n₁₁, n₁₂, n₁₃ and n₁₄ are each independently a number of 0 to 1 (preferably 0 or 1; more preferably 0). As another embodiment, it is also preferred that n₁₁, n₁₂, n₁₃ or n₁₄ iS each independently 1.
   L₁₂ is selected from the group consisting of —C(═O)—, —CH₂—C(═O)—, —C(═O)—CH₂— and —CH(CH₃)—. L₁₂ is more preferably selected from the group consisting of —C(═O)—, —CH₂—C(═O)— and —CH(CH₃)— (further preferably —C(═O) or —CH₂—C(═O)—; further more preferably —CH₂—C(═O)—).
   L₁₄ is C₁₋₅ alkylene (preferably C₁₋₄ alkylene; more preferably methylene, ethylene or n-butylene; further preferably methylene or n-butylene; further more preferably methylene).
   R₁₅ is C₁₋₁₅ alkyl or C₂₋₇ alkenyl (more preferably ethyl, n-propyl, t-butyl, ethyl-cyclopentyl, ethyl-cyclohexyl or ethyl-adamantyl; further preferably ethyl, t-butyl or vinyl; further more preferably t-butyl or vinyl). The C₁₋₁₅ alkyl may or may not (more preferably, may not) include cyclic alkyl.
   The methyl of L₁₂ and the methyl of R₁₅ can be bonded each other to form a ring structure. The ring may or may not be formed. When forming the ring, L₁₂ is —CH(CH₃)—, R₁₅ is C₁₋₁₅ alkyl, and a terminal methyl is used for the bonding. The ring formed is preferably a saturated hydrocarbon ring.

When the hydrocarbon compound (A) is a polymer containing a structure derived from the compound represented by the formula (0) as a repeating unit, the structures derived from the compound represented by the formula (0) may be identical or different each other, and more preferably they are identical. The hydrocarbon compound (A) can be a mixture of multiple types of compounds represented by the formula (0).

Examples of the formula (1) includes the following structures:

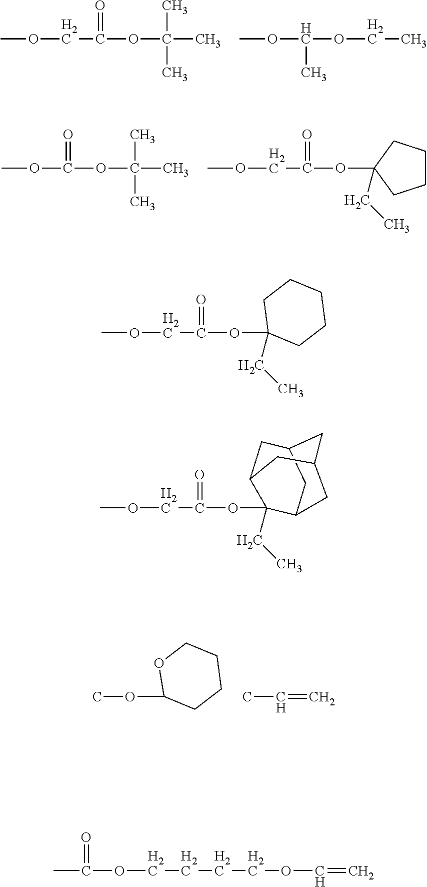

The following compound can be read by the formula (0). The following compound has three Y, and two-thirds (about 67%) are groups represented by the formula (1). The groups represented by the formula (1) are identical. n₁₁=n₁₂=1, n₁₃=n₁₄=0, L₁₂ is —CH(CH₃)—, and R₁₅ can be read as C₃ alkyl (n-propyl). The methyl of L₁₂ and the methyl of R₁₅ are bonded to each other to form a ring.

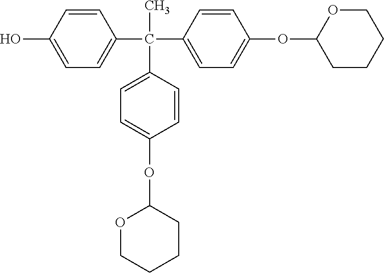 [SMILES: CC(c1ccc(O)cc1)(c1ccc(OC2CCCCO2)cc1)c1ccc(OC2CCCCO2)cc1]

One of the characteristics is that the component (A) has a group represented by the formula (1). Although not to be bound by theory, the group represented by the formula (1) or the binding site using this is deprotected or decrosslinked by receiving an acid. Assuming that the number of groups represented by the formula (1) among the total number of Y is the protection rate, the protection rate is preferably 40 to 100% (more preferably 45 to 100%; further preferably 75 to 100%; further more preferably 100%). Although not to be bound by theory, when the acid in the resist film transfers to the resist overlayer, due to the deprotection or decrosslinking, the solubility of that area to the developer changes, while in the area where the acid does not transfer (immediately above the unexposed area in the case of a positive type resist film) the solubility to the developer does not change. It can be thought that due to this the overlayer pattern is formed.

As one embodiment of the present invention, R₁₅ in the formula (1) is C₁₋₁₅ alkyl. Although not to be bound by theory, it is possible that when the acid transfers from the resist film to the resist overlayer, R₁₅ is deprotected by receiving the acid and the acid receiving part becomes soluble to the developer. For example, when R₁₅ is t-butyl, it is one embodiment of this invention that R₁₅ is deprotected by receiving an acid and converted to a carboxylic acid group.

Preferred examples suitable for this embodiment independently include the following.

X is a group consisting of a combination of C₅₋₁₀ aryl and linear or branched C₁₋₆ alkyl, or a group consisting of a combination of C₅₋₁₀ aryl and cyclic C₁₋₆ alkyl (more preferably a group consisting of a combination of phenyl and branched C₁₋₆ alkyl; further preferably a group consisting of a combination of phenyl and a branched C₂₋₃ alkyl). It is preferred that X is represented by the formula (X-1).
n₀₁ is a number of 1 to 3 (more preferably 1, 2 or 3; further preferably 2 or 3; further more preferably 3).
n₁₁=n₁₂=1.
n₁₃=n₁₄=0.
L₁₂ is selected from the group consisting of —C(═O)—, —CH₂—C(═O)— and —CH(CH₃)— (more preferably —CH₂—C(═O)— and —CH(CH₃)—; further preferably —CH₂—C(═O)—).
R₁₅ is C₁₋₁₅ alkyl (more preferably ethyl, n-propyl, t-butyl, ethyl-cyclopentyl, ethyl-cyclohexyl or ethyl-adamantyl; further preferably t-butyl, ethyl-cyclopentyl, ethyl-cyclohexyl or ethyl-adamantyl; further more preferably t-butyl).
R₂₁ and R₂₄ are linear or branched C₂₋₄ aliphatic hydrocarbon group (more preferably linear or branched C₂, C₃ or C₄ aliphatic hydrocarbon group; further preferably branched C₂, C₃ or C₄ aliphatic hydrocarbon group; further more preferably ethynyl group).
n₂₂ is 0, 1, 2 or 3 (more preferably 0, 2 or 3; further preferably 2 or 3; further more preferably 3).

The (A) component is a compound represented by the formula (0).

The content of the component (C), which is described later, is more preferably 0 to 100 mass % based on the hydrocarbon compound (A) (further preferably 0 to 10 mass %; further more preferably 0 to 1 mass %). It is also preferable to contain no component (C) (0.000 mass %).

The compound represented by the formula (0) has at least one Y and has X as a mother skeleton. It is one embodiment of the present invention that X, which is a mother skeleton, is a C₁₋₆₀ hydrocarbon group and is composed of a linear or branched aliphatic hydrocarbon group, a cyclic hydrocarbon group, or any combination of any of these.

X is preferably represented by the formula (X-1) or the formula (X-2).

The formula (X-1) is as follows:

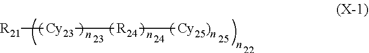

where
R₂₁ and R₂₄ are each independently a linear or branched C₁₋₁₀ aliphatic hydrocarbon group (preferably a linear or branched C₁₋₄ aliphatic hydrocarbon group; more preferably a linear or branched C₂₋₄ aliphatic hydrocarbon group; further preferably a linear or branched C₂, C₃ or C₄ aliphatic hydrocarbon group). It is preferable that the mother skeleton represented by the formula (X-1) takes an embodiment extending and/or branching, from R₂₁ as a starting point. When the mother skeleton represented by the formula (X-1) has a branch as its structure, it is a preferable embodiment that the branch point is R₂₁. The aliphatic hydrocarbon group includes cases other than monovalent. For example, R₂₁ is divalent when n₂₂ is 2.
n₂₂ is a number of 0 to 5 (preferably a number of 0 to 3; more preferably 0, 1, 2 or 3; further preferably 0, 2 or 3; further more preferably 0 or 3). When n₂₂ is 2 or more, groups in parentheses written together with n₂₂ may be identical or different. When there are multiple branches, looking at the formula as a whole, average values are used for n₂₃, n₂₄ and n₂₅. When n₂₂ is 1 or greater, at least one of n₂₃, n₂₄ and n₂₅ is preferably greater than 0. An embodiment in which the group represented by the formula (1) is bonded to Cy₂₃ or Cy₂₅ at the para position is preferred.
Cy₂₃ and Cy₂₅ are each independently a cyclic hydrocarbon group having a C₅-10 ring atom (preferably cyclopentyl, cyclohexyl, phenyl or naphthyl; more preferably cyclohexyl or phenyl; further preferably phenyl).
n₂₃ is each independently a number of 0 to 1 (preferably 0 or 1).
n₂₄ and n₂₅ are each independently a number of 0 to 3 (preferably each independently a number of 0 to 1; more preferably 0 or 1). When n₂₄ is 2 or 3, R₂₄ does not bind to Cy₂₃ in series, but two R₂₄ respectively bind to Cy₂₃. The same is applied also to n₂₅.

The compound on the lower left is a C₁₋₆₀ hydrocarbon group, which can be read as X in the formula (0), and can also be read as the formula (X−1) that is a subordinate (middle genus) concept thereof. In the formula (X−1), R₂₁ is a C₂ aliphatic hydrocarbon group, n₂₂ is 3, and there are three groups in parentheses written together with n₂₂ centering on R₂₁. In the groups in parentheses written together with two n₂₂, n₂₃=1, n₂₄=n₂₅=0, and Cy₂₃ is phenyl. In the groups in parentheses written together with the third n₂₂, n₂₃=n₂₄=n₂₅=1, Cy₂₃ and Cy₂₅ are phenyl, and R₂₄ is a C₃ aliphatic hydrocarbon group. Looking at the formula as a whole, n₂₃=1 and n₂₄=n₂₅=1/3.

The compound on the lower right can be read as the compound on the lower left has three Y. Two of Y are groups represented by the formula (1), and one of Y is-OH. That is, 2/3 (about 67%) of the total number of Y are groups represented by the formula (1).

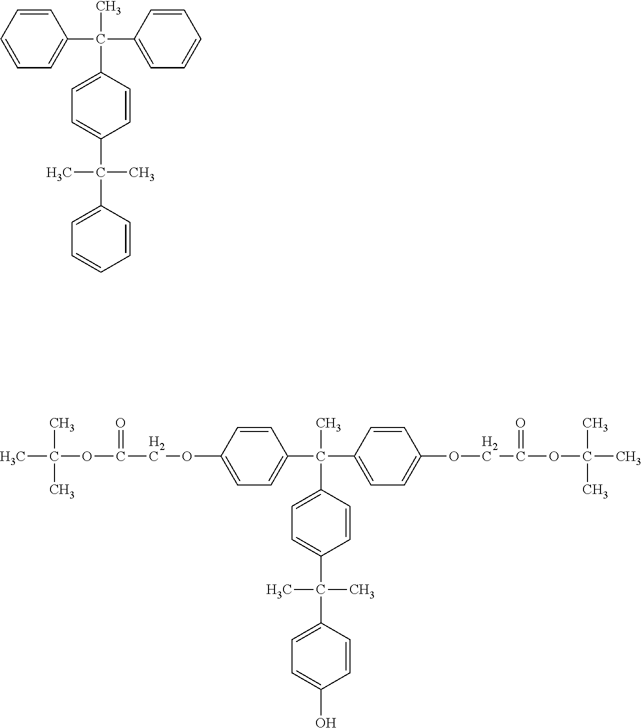

The compound on the lower left is a C₁₋₆₀ hydrocarbon group, which can be read as X in the formula (0), and can also be read as the formula (X-1) that is a subordinate (middle genus) concept thereof. R₂₁ is a linear C₄ aliphatic hydrocarbon group (n-butyl), and n₂₂=0. In the compound on the lower right, the mother skeleton represented by the formula (X-1) has two Y. Two Y are represented by the formula (1) and are the same group. n₁₁=n₁₂=n₁₃=n₁₄=0 and R₁₅ is vinyl. R₂₁ can be read as n-butylene because two Y are substituted with H in R₂₁ and bonded.

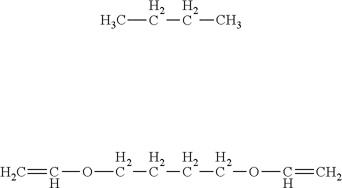

Examples of the structure represented by the formula (X-1) include the following:

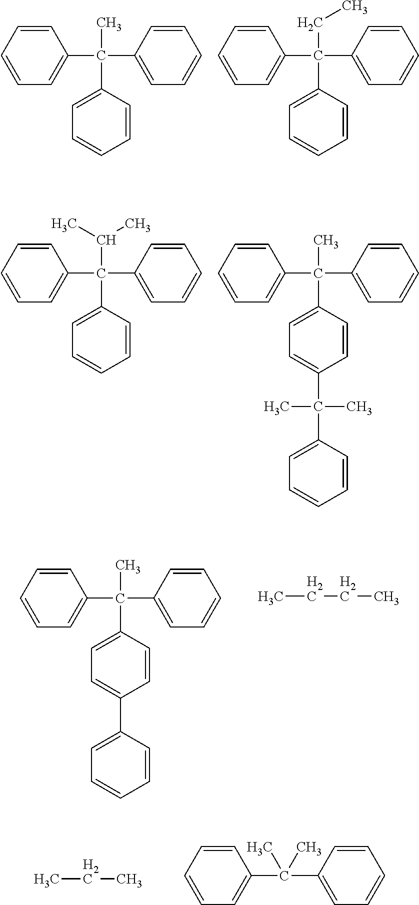

The formula (X-2) is as follows:

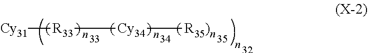

where
   Cy₃₁ and Cy₃₄ are each independently a cyclic hydrocarbon group having a C₅-10 ring atom (preferably cyclopentyl, cyclohexyl, phenyl or naphthyl; more preferably cyclohexyl or phenyl; further preferably phenyl). It is preferable that the mother skeleton represented by the formula (X-2) takes an embodiment extending and/or branching, from Cy₃₁ as a starting point. When the mother skeleton represented by the formula (X-2) has a branch as its structure, it is a preferable embodiment that the branch point is Cy₃₁.
   n₃₂ is a number of 0 to 5 (preferably a number of 0 to 3; more preferably 0, 1, 2 or 3; further preferably 0, 1 or 2; further more preferably 0 or 2). When n₃₂ is 2 or more, groups in parentheses written together with n₃₂ may be identical or different. When there are multiple branches, looking at the formula as a whole, average values are used for n₃₃, n₃₄ and n₃₅. When n₃₂ is 1 or greater, at least one of n₃₃, n₃₄ and n₃₅ is preferably greater than 0. An embodiment in which the group represented by the formula (1) is bonded to Cy₃₁ or Cy₃₄ at the para position is preferred.
   R₃₃ is each independently linear or branched C₁₋₁₀ alkyl (preferably linear or branched C₁₋₄ alkyl; more preferably methyl, ethyl, isopropyl or n-propyl; further preferably methyl or ethyl; further more preferably ethyl).
   R₃₅ is each independently linear or branched C₁₋₁₀ alkyl (preferably linear or branched C₁₋₄ alkyl; more preferably methyl, ethyl, isopropyl or n-propyl; further preferably methyl or ethyl, further more preferably methyl).
   n₃₃ is each independently a number of 0 to 1 (preferably 0 or 1). n₃₄ and n₃₅ are each independently a number of 0 to 3 (preferably each independently a number of 0 to 1; more preferably 0 or 1). When n₃₄ is 2 or 3, Cy₃₄ does not bind to R₃₃ in series, but two Cy₃₄ respectively bind to R₃₃. The same is applied also to n₃₅.

The compound on the lower left is a C₁₋₆₀ hydrocarbon group, which can be read as X in the formula (0), and can also be read as the formula (X-2) that is a subordinate (middle genus) concept thereof. In the formula (X-2), Cy₃₁ is cyclohexyl, n₃₂=2, and groups in parentheses written together with n₃₂ are identical. n₃₃₌₁, n₃₄=n₃₅=0, and R₃₃ is methyl. In the compound on the lower right, the mother skeleton represented by the formula (X-2) has two Y, and the two Y are both groups represented by the formula (1) and are the same group. n₁₁=n₁₂=n₁₃=n₁₄=0, and R₁₅ is vinyl. Y is bonded to the methyl of R₃₃, and R₃₃ becomes a methylene linker.

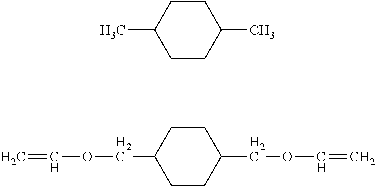

The compound on the lower left is a C₁₋₆₀ hydrocarbon group, which can be read as X in the formula (0), and can also be read as the formula (X-2) that is a subordinate (middle genus) concept thereof. In the formula (X-2), Cy₃₁ is cyclohexyl, and n₃₂₌₂. In the compound on the lower right, the mother skeleton represented by the formula (X-2) has three Y, and all three Y are groups represented by the formula (1) and are the same group. n₁₁=0, and n₁₂=n₁₃=n₁₄=1. L₁₂ is —C(═O)—, and L₁₄ is C₄ alkylene. R₁₅ is vinyl.

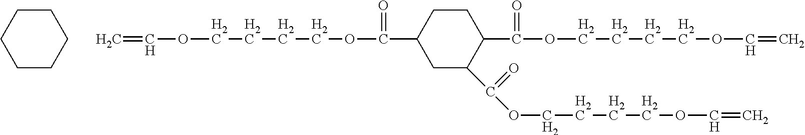 [SMILES: C1CCCCC1 ; C=COCCCCOC(=O)C1CCC(C(=O)OCCCCOC=C)C(C(=O)OCCCCOC=C)C1]

Examples of the structure represented by the formula (X-2) include the following:

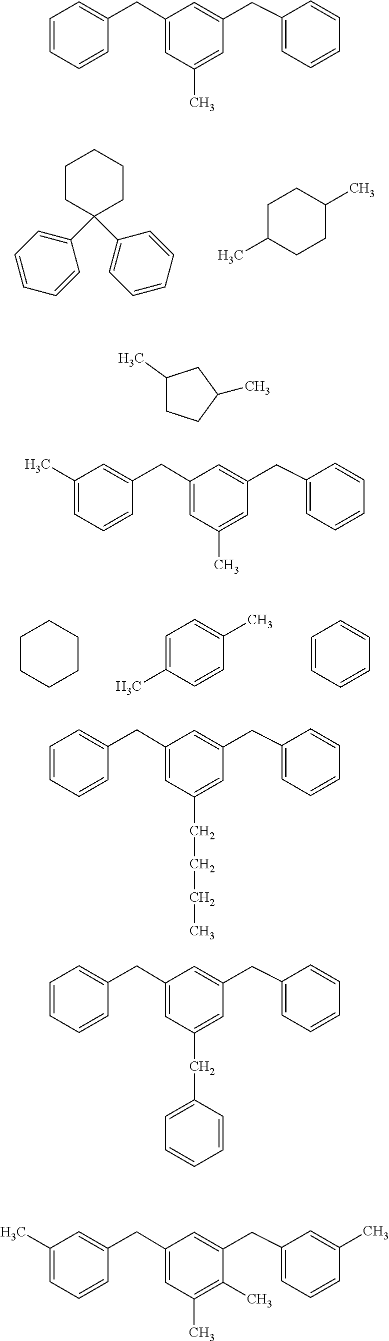

In a preferred embodiment of the present invention, the component (A) is a compound represented by the formula (0).

In a preferred embodiment of the present invention, the component (A) is a polymer (hereinafter referred to as the polymer (A)) comprising a structure derived from the compound represented by the formula (0) (hereinafter referred to as the formula (0) structure) as a repeating unit.

The polymer (A) can be a copolymer containing repeating units other than the formula (0) structure in a range that the scope of the present invention is not impaired. Examples of the repeating unit other than the formula (0) structure include structures derived from compounds represented by the formula (c) described later.

Exemplified embodiment of the polymer (A) includes a polymer having the following structure:

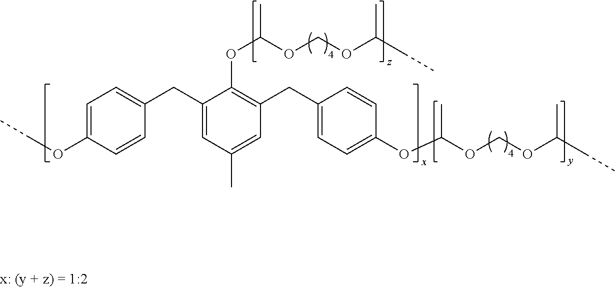

The above polymer can be obtained by polymerizing the compound on the lower left (represented by the formula (0)) and the compound on the lower right (represented by the formula (c)) at a molar ratio of 2:1.

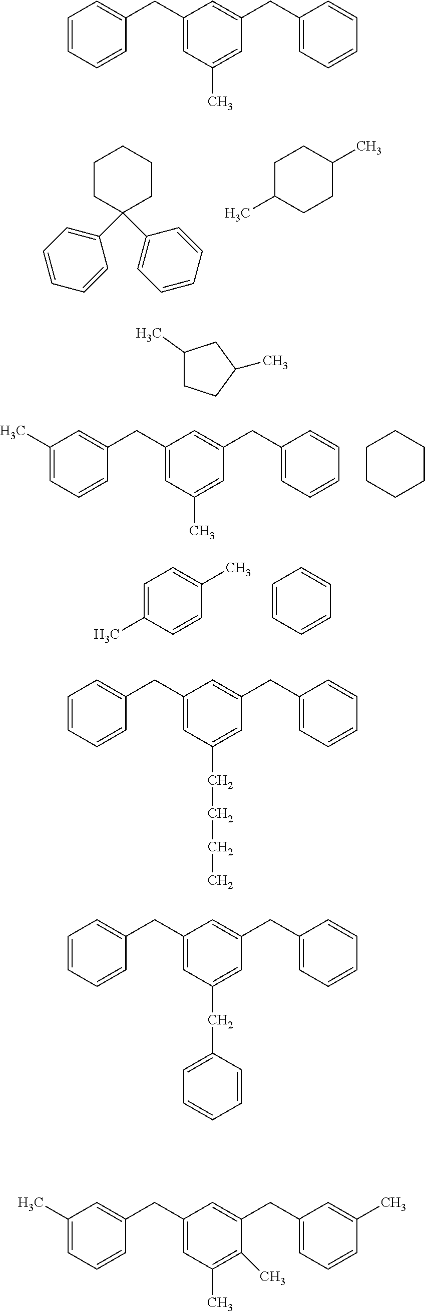

When the polymer (A) is a copolymer, it is preferably alternating copolymerization, random copolymerization, block copolymerization, graft copolymerization, or any mixture of any of these (more preferably alternating copolymerization, random copolymerization or block copolymerization; further preferably random copolymerization or block copolymerization; further more preferably random copolymerization).

The molecular weight of the component (A) is preferably 100 to 80,000. When the component (A) is a polymer, the molecular weight means the mass average molecular weight (Mw), which is the average mass molecular weight converted to polystyrene standard measured using gel permeation chromatography.

When the component (A) is a compound represented by the formula (0), its molecular weight is more preferably 100 to 1,000 (further preferably 100 to 900; further more preferably 120 to 800). When the component (A) is a polymer, its molecular weight (Mw) is more preferably 5,000 to 60,000 (further preferably 10,000 to 50,000; further more preferably 20,000 to 40,000).

As one embodiment of the present invention, R₁₅ in the formula (1) is C₂₋₇ alkenyl. Although not to be bound by theory, it is possible that the site crosslinked via R₁₅ is decrosslinked by accepting the acid transferred from the resist film to the resist overlayer, and the acid-accepting site is solubilized to the developer. For example, when R₁₅ is vinyl, the crosslinked sites can be decrosslinked by accepting the acid.

Preferred examples suitable for this embodiment independently include the following.

X is preferably a group consisting of cyclic C₅₋₁₀ alkyl, a group consisting of linear C₁₋₆ alkyl, a group consisting of branched C₃₋₆ alkyl, or a group consisting of any combination of any of these (more preferably a group consisting of cyclic C₅₋₁₀ alkyl, a group consisting of linear C₁₋₆ alkyl, or a group consisting of any combination of any of these; further preferably a group consisting of cyclic C₅₋₆ alkyl, or a group consisting of linear C₁₋₆ alkyl; further more preferably cyclohexyl or n-butyl). It is preferred that X is represented by the formula (X-1). As another embodiment, it is preferable that X is represented by the formula (X-2).
n₀₁ is a number of 1 to 3 (more preferably 1, 2 or 3; further preferably 2 or 3; further more preferably 2).
n₁₁ is 0 or 1 (more preferably 0).
n₁₂ is 0 or 1 (more preferably 0).
L₁₂ is selected from —C(═O)— or —C(═O)—CH₂— (more preferably —C(═O)—).
n₁₃ is 0 or 1 (more preferably 0).
n₁₄ is 0 or 1 (more preferably 0).
L₁₄ is methylene, ethylene or n-butylene (more preferably methylene or n-butylene; further preferably n-butylene).
R₁₅ is C₂₋₇ alkenyl (more preferably vinyl).
R₂₁ and R₂₄ are each independently a linear or branched C₁₋₄ aliphatic hydrocarbon group (more preferably a linear or branched C₂, C₃ or C₄ aliphatic hydrocarbon group; further preferably n-butyl group).
n₂₂ is 0, 1, 2 or 3 (more preferably 0, 2 or 3; further preferably 0 or 3; further more preferably 0).
Cy₂₃ and Cy₂₅ are each independently cyclohexyl or phenyl (more preferably cyclohexyl).
n₂₃ is 0 or 1 (more preferably 0).
n₂₄ and n₂₅ are each independently 0 or 1 (more preferably 0).

It is more preferable embodiment that the composition of the present invention contains a component (C) described later, or is a copolymer in which the polymer (A) further comprises a structure derived from the compound represented by the formula (c). “contains a component (C)” means that the content of the component (C) is preferably 50 to 200 mass % based on the component (A).

The content of the component (A) is preferably 0.01 to 15 mass % (more preferably 0.05 to 10 mass %; further preferably 0.10 to 5 mass %; further more preferably 0.10 to 4 mass %) based on the composition according to the present invention.

As described above, the polymer (A) can be a copolymer containing repeating units other than the formula (0) structure in a range that the scope of the present invention is not impaired. It is a preferred embodiment of the present invention that as a repeating unit other than the formula (0) structure, the structure derived from the compound represented by the formula (c) constitutes the polymer (A) as a repeating unit. A more preferred example of the structure derived from the compound represented by the formula (c) is the compound represented by the formula (c) itself. The molecular weight and content in that case are described as the polymer (A) rather than as the component (C). Details are as described above.

When the polymer (A) is a copolymer, preferably {number of repeating units of the formula (0) structure}/{number of repeating units other than the formula (0) structure} is 25 to 400% (more preferably 50 to 300%; further preferably 150 to 250%). It is preferable to seek the ratio of the number of repeating units by molar ratio. When the polymer (A) is a copolymer, the molar ratio of the hydroxy in the structure derived from the compound represented by the formula (c) and the group represented by the formula (1) in the structure of the formula (0) is preferably is 2:1 to 1:2 (more preferably 3:2 to 2:3; further preferably 4:3 to 3:4).

### (B) Solvent

The composition according to the present invention comprises a solvent (B).

The solvent (B) comprises a solvent (B1) represented by the formula (b1).

R₂₁—O—R₂₂ (b1)

where

R₂₁ and R₂₂ are each independently C₁₋₈ alkyl (preferably C₃₋₆ alkyl). They can be linear, branched or cyclic (preferably linear or cyclic; more preferably linear).

R₂₁ and R₂₂ may be different or identical, but are preferably identical.

R₂₁ and R₂₂ are each independently preferably methyl, ethyl, n-propyl, isopropyl, n-butyl, t-butyl, n-pentyl, isopentyl, cyclopentyl or cyclohexyl (more preferably methyl, n-butyl, n-pentyl, isopropyl, cyclopentyl or cyclohexyl; further preferably n-butyl).

Examples of the solvent (B1) include dibutyl ether, dipentyl ether, diisopentyl ether, dicyclopentyl ether, dicyclohexyl ether, cyclopentyl methyl ether and the like.

As one embodiment of the present invention, the solvent (B) preferably consists essentially only of the solvent (B1) (more preferably consists only of the solvent (B1)).

The solvent (B) preferably comprises a solvent (B2) different from the solvent (B1) (more preferably consists essentially only of the solvent (B1) and the solvent (B2); further preferably consists only of the solvent (B1) and the solvent (B2)).

Preferably, the solvent (B2) is cyclohexanone, cyclopentanone, propylene glycol monomethyl ether (PGME), propylene glycol monoethyl ether, propylene glycol monopropyl ether, propylene glycol monobutyl ether, propylene glycol dimethyl ether, propylene glycol diethyl ether, propylene glycol monomethyl ether acetate (PGMEA), propylene glycol monoethyl ether acetate, propylene glycol monopropyl ether acetate, γ-butyrolactone, ethyl lactate, 2-propanol (IPA) or any combination of any of these. The solvent (B2) is preferably PGME, PGMEA or any combination of any of these. When the solvents contained in the solvent (B2) are two kinds, their mass ratio is preferably 100:1 to 1:100 (more preferably 50:1 to 1:50; further preferably 30:1 to 1:30).

The solvent (B2) can contain water. The content of water is preferably 5 mass % or less (more preferably 1 mass % or less; further preferably 0.001 mass % or less) based on the solvent (B). It is also a preferred embodiment of the present invention that the solvent (B2) contains no water (0.000 mass %).

Although not to be bound by theory, it can be thought that the solvent (B) of the composition according to the present invention can contribute to the formation of thickened film pattern by dissolving the solid components (components other than the solvent (B)) while avoiding dissolving the underlying resist film.

The content of the solvent (B) is preferably 70 to 99.99 mass % (more preferably 80 to 99.99 mass %; further preferably 95 to 99.99 mass %; further more preferably 95 to 99.90 mass %) based on the composition according to the present invention.

The content of the solvent (B1) is preferably 70 to 100 mass % (more preferably 80 to 100 mass %; further preferably 90 to 100 mass %) based on the solvent (B).

The content of the solvent (B2) is preferably 0 to 30 mass % (more preferably 0 to 20 mass %; further preferably 0.1 to 10 mass %) based on the solvent (B).

### (C) Hydroxy-Containing Compound

The composition according to the present invention can further comprise a hydroxy-containing compound (C) represented by the formula (c).

The formula (c) is as follows:

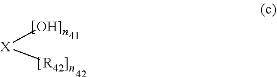

R₄₂ is C₁₋₆ alkoxy (preferably excluding t-butoxy), —(C═O)—R₀₃, —(C═O)—O—R₀₄, —(C═O)—N(R₀₅)₂, —O—(C═O)—R₀₆ or —NR₀₇—(C═O)—R₀₈. R₄₂ is preferably C₁₋₆ alkoxy (more further preferably methoxy).
n₄₁ is a number of 1 to 10 (preferably a number of 1 to 5; more preferably a number of 1 to 3; further preferably 1, 2 or 3).
n₄₂ is a number of 0 to 10 (preferably a number of 0 to 3; more preferably a number of 0 to 1; further preferably 0 or 1; further more preferably 0).
X, R₀₃, R₀₄, R₀₅, R₀₆, R₀₇ and R₀₈ each independently have the same definition and preferred examples as those of the same symbols in the formula (0) unless otherwise specified.

When X of the component (C) is represented by the formula (X-2), Cy₃₁ and Cy₃₄ of the component (C) are preferably phenyl. Although describing for clarity, for X, R₀₃, R₀₄, R₀₅, R₀₆, R₀₇ and R₀₈ in the component (A) as well as for these in the component (C), different ones can be each independently selected. For example, Cy₃₁ and Cy₃₄ in the component (A) and Cy₃₁ and Cy₃₄ in the component (C) can be each independently selected. For example, it is an embodiment of the present invention that Cy₃₁ in the component (A) is cyclohexyl, and Cy₃₁ and Cy₃₄ in the component (C) are phenyl.

The hydroxy-containing compound (C) (component (C)) represented by the formula (c) has at least one OH and has X as a mother skeleton. It is one of the preferred embodiments of the present invention that X that is the mother skeleton is a C₁₋₆₀ hydrocarbon group and is composed of an aliphatic hydrocarbon group, a cyclic hydrocarbon group, or any combination of any of these.

X in the component (C) is preferably represented by the formula (X-1) or the formula (X-2) (more preferably (X-2)).

Examples of the component (C) include the following compounds:

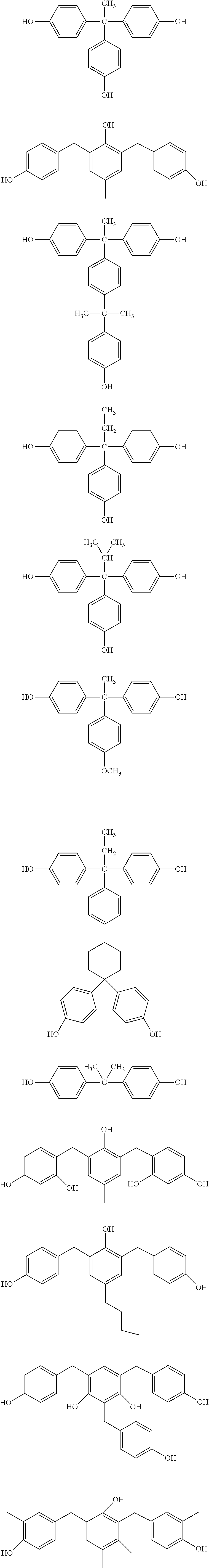

The molecular weight of the component (C) is preferably 200 to 800 (more preferably 200 to 600; further preferably 200 to 450).

The content of the component (C) is preferably 50 to 200 mass % (more preferably 60 to 150 mass %; further preferably 60 to 110 mass %) based on the hydrocarbon compound (A). It is also a preferred embodiment of the present invention that no component (C) is contained (0.000 mass %).

In the composition of the present invention, the molar ratio of the hydroxyl in the component (C) and the group represented by the formula (1) in the component (A) is preferably 2:1 to 1:2 (more preferably is 3:2 to 2:3; further preferably 4:3 to 3:4).

As one embodiment of the present invention, R₁₅ in the formula (1) is C₂₋₇ alkenyl, and the composition of the present invention does not substantially contain the component (C). Although not to be bound by theory, in the case of a resist film having a hydroxy group on the surface, it is protected by bonding R₁₅ with the hydroxy group, and the bonding portion is deprotected by accepting the acid transferred from the resist film to the resist overlayer, and the acid-accepting portion can be solubilized to the developer. For example, when R₁₅ is vinyl, the bonding site with hydroxy (acetal structure) can be deprotected by accepting the acid. It is a preferred embodiment of the present invention that transferring in the above “acid transferred from the resist film to the resist overlayer” is accelerated by heating in the step (3). As one preferred embodiment, hydroxy groups are present on the surface of the resist film to which the composition of the present invention is applied.

Preferred examples suitable for this embodiment independently include the following.

X is preferably a group consisting of cyclic C₅₋₁₀ alkyl, a group consisting of linear C₁₋₆ alkyl, a group consisting of branched C₃₋₆ alkyl, or a group consisting of any combination of any of these (more preferably a group consisting of cyclic C₅₋₁₀ alkyl, a group consisting of linear C₁₋₆ alkyl, or a group consisting of any combination of any of these; further preferably a group consisting of cyclic C₅₋₆ alkyl, or a group consisting of linear C₁₋₆ alkyl; further more preferably cyclohexyl). It is preferred that X is represented by the formula (X-2). As another embodiment, X is also preferably represented by the formula (X-1).
n₀₁ is a number of 1 to 3 (more preferably 1, 2 or 3; further preferably 1 or 2; further more preferably 1).
n₁₁ is 0 or 1 (more preferably 0).
n₁₂ is 0 or 1 (more preferably 0).
L₁₂ is selected from —C(═O)— or —C(═O)—CH₂— (more preferably —C(═O)—).
n₁₃ is 0 or 1 (more preferably 0).
n₁₄ is 0 or 1 (more preferably 0).
L₁₄ is methylene, ethylene or n-butylene (more preferably methylene or n-butylene; further preferably n-butylene).
R₁₅ is C₂₋₇ alkenyl (more preferably vinyl).
Cy₃₁ and Cy₃₄ are each independently cyclohexyl or phenyl (more preferably cyclohexyl).
n₃₂ is 0, 1, 2 or 3 (more preferably 0, 1 or 2; further preferably 0 or 2; further more preferably 0).
R₃₃ and R₃₅ are each independently methyl, ethyl, isopropyl or n-propyl (more preferably methyl or ethyl; further preferably methyl).
n₃₃ is 0 or 1 (more preferably 1).
n₃₄ and n₃₅ are each independently 0 or 1 (more preferably 0).

The composition of the present invention does not substantially contain the component (C). The term “not substantially contain” means that the content of the component (C) is 0 to 5 mass % (more preferably 0.00 to 1 mass %; further preferably 0.00 to 0.1 mass %; further more preferably 0.000 mass %) based on the component (A). When the component (A) of the present invention is a polymer, the polymer does not contain a structure derived from the compound represented by the formula (c). The component (A) of the composition of the present invention is not a polymer but a compound represented by the formula (0).

### (D) Acid Generator

The composition according to the present invention can further comprise an acid generator (D).

In a preferred embodiment, when the component (D) reacts with an acid, it releases an acid with an acid dissociation constant pKa (H₂O) of −14 to 8 (more preferably −14 to 4; further preferably −12 to 2; further more preferably −10 to 1).

More preferably, the resist film formed under the resist overlayer comprises a PAG (D′), and the PAG (D′) releases an acid with an acid dissociation constant pKa (H₂O) of −20 to 1.4 (preferably −16 to 1.4; more preferably −16 to 1.2; further preferably −16 to 1.1). Although not to be bound by theory, it can be thought that the effect of the present invention can be more exhibited by transferring the acid derived from the component (D′) from the resist film to the resist overlayer to salt-exchange with the component (D), thereby diffusing the acid into the resist overlayer for a longer distance. It is one embodiment of the present invention that the acid generated from the component (D) by salt-exchange is a weak acid, and has a lower acidity than the strong acid generated from the photo-strong acid generator (E) by light acceptance described later.

A preferred embodiment of the acid generator (D) includes a salt of m-valent Cation and m-valent Anion. m is preferably 1 or 2 (more preferably 2).

The Cation is preferably obtained from triarylsulfonium or diaryliodonium (more preferably triarylsulfonium). The aryl in the Cation is preferably phenyl or naphthyl (more preferably phenyl). The aryl may be unsubstituted or substituted (more preferably unsubstituted). The number of substituents bonded to one aryl to be substituted is preferably an integer of 1 to 5 (more preferably 1, 2 or 3; further preferably 1), and the substituent is preferably halogen, methyl or methoxy (more preferably fluorine, methyl or methoxy; further preferably methyl).

The Anion is preferably obtained from sulfonic acid or carboxylic acid (more preferably sulfonic acid). The sulfonic acid or carboxylic acid has alkyl or aryl (more preferably alkyl). The alkyl is preferably C₁₋₄ alkyl (more preferably methyl). H in the alkyl may be unsubstituted or substituted (preferably substituted). All or a part of (more preferably all) the H of one alkyl to be substituted are replaced with a substituent. The substituent is preferably halogen (more preferably fluorine). The aryl is preferably C₆₋₁₀ aryl (more preferably phenyl or naphthyl; further preferably phenyl). The H in the aryl may be unsubstituted or substituted (preferably substituted). The number of substituents bonded to one aryl to be substituted is preferably an integer of 1 to 5 (more preferably 1, 2 or 3; further preferably 1), and the substituent is preferably halogen, methyl or methoxy (more preferably fluorine, methyl or methoxy; further preferably methyl).

Examples of the component (D) include triphenylsulfonium trifluoromethanesulfonate, triphenylsulfonium trifluoroacetate, triphenylsulfonium methanesulfonate, triphenylsulfonium 4-methylbenzene-sulfonate, (4-methoxyphenyl) diphenylsulfonium trifluoromethanesulfonate and the like.

The composition of the present invention may or may not contain the component (D). The content of the component (D) is preferably 0.01 to 40 mass % (more preferably 0.10 to 20 mass %; further preferably 0.20 to 10 mass %) based on the component (A).

### (E) Photo-Strong Acid Generator

The composition according to the present invention can further comprise a photo-strong acid generator (E), but preferably does not substantially contain it. The component (E) releases an acid with an acid dissociation constant pKa (H₂O) of −20 to 1.4 (preferably −16 to 1.4; further preferably −16 to 1.2; further more preferably −16 to 1.1) by exposure.

The content of the component (E) is preferably 0 to 1.00 mass % (more preferably 0.00 to 0.005 mass %; further preferably 0.00 to 0.001 mass %) based on the component (A). It is also a preferred embodiment of the present invention that no component (E) is contained (0.000 mass %). Although not to be bound by theory, it can be thought that even if no component (E) that generates a strong acid is contained in the overlayer of the present invention, the acid that transfers from the underlying resist film can be accepted.

### (F) Surfactant

The composition according to the present invention can further comprise a surfactant (F). The coatability can be improved by including the surfactant (F). Examples of the surfactant that can be used in the present invention include (I) anionic surfactants, (II) cationic surfactants or (III) nonionic surfactants, and more particularly (I) alkyl sulfonate, alkyl benzene sulfonic acid and alkyl benzene sulfonate, (II) lauryl pyridinium chloride and lauryl methyl ammonium chloride and (III) polyoxyethylene octyl ether, polyoxyethylene lauryl ether, polyoxyethylene acetylenic glycol ether, fluorine-containing surfactants (for example, Fluorad (3M), Magaface (DIC) and Surflon (AGC)), and organic siloxane surfactants (for example, KF-53 and KP341 (Shin-Etsu Chemical)).

These surfactants can be used alone or in any combination of any two or more of these.

The content of the surfactant (F) is preferably 0 to 10 mass % (more preferably 0.001 to 10 mass %; further preferably 0.1 to 5 mass %) based on the hydrocarbon compound (A). It is also an embodiment of the present invention that no surfactant (F) is contained (0.00 mass %).

### (G) Additive

The composition according to the present invention can further comprise other additive (G) different from the components (A) to (F) described above. The additive (G) is preferably a surface leveling agent, an acid, a base, a substrate adhesion enhancer, an antifoaming agent, or any combination of any of these (more preferably a base).

Examples of the base include trialkyl amines.

The content of the additive (G) is preferably 0 to 10 mass % (more preferably 0.001 to 10 mass %; further preferably 0.001 to 1 mass %; further more preferably 0.01 to 0.5 mass %) based on the hydrocarbon compound (A). In one preferred embodiment of the present invention, no additive (G) is contained (0.000 mass %).

### Method for Manufacturing a Resist Overlayer Pattern and a Resist Pattern

The method for manufacturing a resist overlayer pattern and a resist pattern according to the present invention comprises the following steps:
(1) applying a resist composition above a substrate and heating the resist composition to form a resist film;
(2) optionally exposing the resist film;
(3) applying a developable resist overlayer composition directly on the resist film and heating the resist overlayer composition to form a resist overlayer;
(4) optionally exposing the resist film and the resist overlayer, provided that at least one of the exposures of (2) and (4) is performed;
(5) transferring the acid in the resist film to the resist overlayer; and
(6) developing the resist overlayer and the resist film using a developer to form a resist overlayer pattern and a resist pattern.

Each step is explained hereinafter using the figures. The numbers in parentheses indicating the steps mean the order.

### Step (1)

In the step (1), a resist composition is applied above a substrate and the resist composition is heated to form a resist film.

Examples of the substrate include a silicon/silicon dioxide coated substrate, a silicon nitride substrate, a silicon wafer substrate, a glass substrate and an ITO substrate.

The resist composition is not particularly limited, but from the viewpoint of forming a fine resist pattern with high resolution, it is preferably a chemically amplified resist composition, for example, a chemically amplified PHS-acrylate hybrid EUV resist composition. It is also a preferred embodiment that the resist composition contains a photoacid generator (D′) (PAG (D′) described above). As the resist composition that can be used in the manufacturing method of the present invention, the pattern-forming composition or radiation-sensitive resin composition described in JP 2021-73367 A or JP 2020-8842 A can be used. The resist composition in the manufacturing method of the present invention is preferably positive type.

A general high-resolution positive type resist composition comprises a combination of an alkali-soluble resin whose side chain is protected by a protective group and a photoacid generator. When a resist layer formed from such a composition is irradiated with ultraviolet ray, electron beam, extreme ultraviolet ray or the like, the photoacid generator releases an acid in the irradiated area (exposed area), and a protective group bonded to alkali-soluble resin is dissociated by the acid (hereinafter referred to as deprotection). Since the deprotected alkali-soluble resin is soluble to an alkali developer, it is removed by development processing.

A resist composition is applied above a substrate by a proper method. In the present invention, “above a substrate” includes the case of applying directly on a substrate and the case of applying via another layer. For example, a resist underlayer (for example, a SOC (Spin On Carbon) and/or an adhesion enhancing film) may be formed directly on a substrate, and a resist composition may be applied directly thereon. Preferably, a resist composition is applied directly on a substrate. In another preferred embodiment, a SOC is formed directly on a substrate, an adhesion enhancing film is formed directly on the SOC, and a resist composition is applied directly thereon.

The application method is not particularly limited, but examples thereof include application by spin coating.

The substrate on which the resist composition is applied is heated to form a resist layer. This heating is also called pre-baking, and is performed by, for example, a hot plate. The heating temperature is preferably 90 to 250° C. (more preferably 90 to 200° C.; further preferably 100 to 130° C.). The temperature is the heating surface temperature of the hot plate. The heating time is preferably 30 to 300 seconds (more preferably 30 to 120 seconds; further preferably 45 to 90 seconds). The heating is preferably performed in air or nitrogen gas atmosphere (more preferably in air atmosphere).

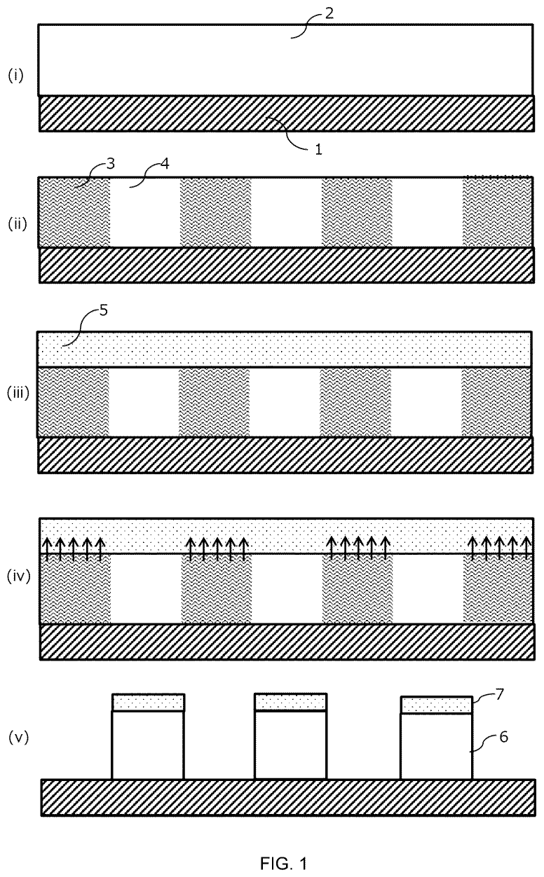

FIG. 1 (i) is a schematic view showing a state in which a resist film 2 is formed on a substrate 1. The film thickness of the resist layer is preferably 10 to 50 nm (more preferably 25 to 50 nm).

### Step (2)

In the step (2), the resist film is optionally exposed. The exposure is performed, optionally through a mask.

Although the wavelength of the radiation (light) used for exposure is not particularly limited, it is preferable to perform exposure with light having a wavelength of 13.5 to 248 nm. In particular, KrF excimer laser (wavelength: 248 nm), ArF excimer laser (wavelength: 193 nm), EUV (extreme ultraviolet ray, wavelength: 13.5 nm) and the like can be used. EUV light is more preferred. These wavelengths allow a range of ±1%.

After exposure, post-exposure bake (PEB) can also be performed as necessary. The PEB temperature can be selected from the range of 70 to 150° C. (preferably 100 to 140° C.). The PEB heating time can be selected from the range of 0.3 to 5 minutes (preferably 0.5 to 2 minutes).

FIG. 1 (ii) is a schematic view showing a state in which the resist film 2 in the case of using a typical positive type chemically amplified resist composition is exposed through a mask. In the exposed area 3, an acid is released from the photoacid generator, thereby deprotecting the polymer and increasing alkali solubility. In the unexposed area 4, alkali solubility of the polymer does not change.

### Step (3)

In the step (3), a developable resist overlayer composition is applied directly on the resist film, and then the resist overlayer composition is heated to form a resist overlayer.

The developable resist overlayer composition is preferably a composition according to the above-described present invention comprising a hydrocarbon compound (A) and a solvent (B).

The application method is not particularly limited, but examples thereof include application by spin coating.

The substrate to which the developable resist overlayer composition is applied is heated to form a resist overlayer. The heating is performed by, for example, a hot plate. The heating temperature is preferably 45 to 150° C. (more preferably 80 to 120° C.). The heating time is preferably 30 to 180 seconds (more preferably 45 to 90 seconds).

The heating is preferably performed in air or nitrogen gas atmosphere (more preferably in air atmosphere). Although not to be bound by theory, it can be thought that when exposure in the step (2) is performed, the acid generated from the photoacid generator in the resist film diffuses by the heating in the step (3). As in the step (5) to be described later, an embodiment that the acid transfers from the resist film to the resist overlayer of the present invention due to this diffusion is more preferable.

The thickness of the resist overlayer formed in the step (3) is preferably 1 to 10 nm (more preferably 2 to 8 nm; further preferably 5 to 7 nm). It is one preferred embodiment that the thickness of the resist film does not substantially decrease even when the resist overlayer composition of the present invention is applied. In particular, the amount of decrease in the thickness of the resist film (not including the resist overlayer) before and after the above-described application is preferably 0 to 15% (more preferably 0 to 10%; further preferably 0.1 to 5%; further more preferably 0.1 to 1%). It is also a preferred embodiment of the present invention that the thickness of the resist film does not decrease (the amount of decrease is 0%) before and after the above-described application.

### Step (4)

In the step (4), the resist film and the resist overlayer are optionally exposed.

However, at least one of the exposures of steps (2) and (4) must be performed. The exposure conditions for the step (4) are the same as those for the step (2).

Preferably, the exposure in the step (2) is performed and the exposure in the step (4) is not performed. In this case, the resist film before the resist overlayer is formed is exposed, and that of after the resist overlayer is formed is not exposed. That is, the step (4) can be omitted in the manufacturing method of the present invention.

FIG. 1 (iii) is a schematic view showing a state in which the resist film 2 is formed, then exposed, and then the resist overlayer 5 is formed.

It is also preferable to perform heating after exposure (PEB). Preferably, the step (2) is followed by a step (2-2) of heating and/or the step (4) is followed by a step (4-2) of heating. The PEB can diffuse the acid generated in the exposed area, for example, to make the presence of the acid more uniform in the exposed area. It is also a preferred embodiment that the heating of (2-2) and (4-2) are not performed. If exposure is performed in the step (2), the heating in the step (3) can make the acid diffuse.

### Step (5)

In the step (5), the acid in the resist film transfers to the resist overlayer. The acid transfer can also be accelerated by heating. The acid transfer can occur during heating of the resist overlayer in the step (3) (i.e., the step (5) occurs simultaneously with the step (3)), or can occur after the step (3). More preferably, the transfer of the acid in the step (5) occurs during the heating of the resist overlayer in the step (3).

Preferably, the solubility of the resist overlayer to the developer changes by the acid transferred in the step (5). In a preferred embodiment, the acid generated from the photo-strong acid generator (E) in the resist film is ion-exchanged with the acid generator (D) in the resist overlayer, the acid derived from the acid generator (D) diffuses into the resist overlayer, and the solubility of the resist overlayer to the developer changes.

In a more preferred embodiment, it can be thought that in the area where the acid transfer does not occur (unexposed area in the case of a positive type resist), a hydrocarbon compound (A) becomes insoluble to the developer by binding to the resist film when the resist overlayer is formed in the step (3), and in the area where the acid transfer occurs (exposed area in the case of a positive resist), due to the acid that transferred in the step (5), the resist overlayer becomes soluble to the developer, and the resist overlayer can also be patterned.

FIG. 1 (iv) is a schematic view showing a state in which the acid transfer from the resist film to the resist overlayer occurs. In a positive type, the acid transfers to the exposed area of the resist film and the resist overlayer directly on the exposed area, and the area to which the acid transferred becomes alkali-soluble like in the resist film, but the acid transfer does not occur in the unexposed area, so that the solubility of the resist overlayer to the developer does not change.

After the step (5) and before development, it is also preferable to perform surface cleaning on the resist overlayer to remove the upper portion of the resist overlayer. For surface cleaning, one having the same composition as the solvent (B) in the composition according to the present invention can be used.

### Step (6)

In the step (6), the resist overlayer and the resist film are developed using a developer to form a resist overlayer pattern and a resist pattern (hereinafter referred to as the thickened film pattern).

Examples of the method for applying the developer include a paddle method, a dip method and a spray method. The temperature of the developer is preferably 5 to 50° C. (more preferably 25 to 40° C.), and the development time is preferably 15 to 120 seconds (more preferably 20 to 60 seconds). After application of the developer, the developer is removed.

The developer is preferably an alkaline aqueous solution or an organic solvent (more preferably an alkaline aqueous solution). Examples of the alkaline aqueous solution include aqueous solutions containing: inorganic alkalis such as sodium hydroxide, potassium hydroxide, sodium carbonate and sodium silicate; organic amines such as ammonia, ethylamine, propylamine, diethylamine, diethylaminoethanol and triethylamine; quaternary amins such as tetramethylammonium hydroxide (TMAH), and the like (more preferably a TMAH aqueous solution; further preferably a 2.38 mass % TMAH aqueous solution).

To the developer, the above-described surfactant can be also further added.

FIG. 1 (v) shows a state in which a developer is applied to the resist film and the resist overlayer, the developer is removed, and a resist pattern 6 and a resist overlayer pattern 7 are formed. When looking at the resist pattern 6 and the overlayer pattern 7 being combined, they form a thickened film pattern.

When (the total of film thickness of the resist pattern and film thickness of the resist overlayer)−(film thickness of the resist pattern formed in the same manner except that the film-thickening solution is not applied) is taken as an amount of film-thickening, the amount of film-thickening is preferably 1 to 10 nm; more preferably 2 to 8 nm; further preferably 3 to 7 nm; further more preferably 4 to 6 nm. Although not to be bound by theory, it can be thought that while the thickness of the resist film is generally thin in high-definition lithography techniques such as EUV exposure, it becomes possible to ensure the durability as a mask when used in a later step, for example, as an etching mask.

The method according to the present invention can further comprises the following Step (7):

(7) washing the resist overlayer pattern and the resist pattern with a cleaning liquid and removing the cleaning liquid from between the patterns.

In order to remove local film residues, the resist overlayer pattern and the resist pattern can be cleaned using the cleaning liquid. Cleaning liquids include water-soluble cleaning liquids or organic solvent cleaning liquids (for example, IPA, PGME, PGMEA, PGEE and nBA are included). In a preferred embodiment of the present invention, the cleaning liquid is a rinse liquid, and the rinsing treatment is performed by replacing the developer with the rinse liquid. The rinsing treatment can be preferably performed with a water-soluble rinse liquid. The lower limit of water (DIW) content in the water-soluble rinse liquid is preferably 90 mass % (more preferably 95 mass %; further preferably 98 mass %; further more preferably 99.99 mass %) based on the total liquid. Components other than water contained in the water-soluble rinse liquid are preferably 1,000 ppm or less (more preferably 100 ppm or less) based on the total liquid.

### Method for Manufacturing a Processed Substrate and a Device

The method for manufacturing a processed substrate according to the present invention comprises the following steps: forming a resist overlayer pattern and a resist pattern by the method described above; and

(8) processing using the resist overlayer pattern and the resist pattern as a mask.

### Step (8)

In the step (8), processing is performed using the resist overlayer pattern and the resist pattern as a mask. The resist overlayer pattern and the resist pattern are preferably used as a mask for processing the resist underlayer or the substrate (more preferably the substrate). In particular, using the thickened film pattern as a mask, various substrates that serve as an underlying material can be processed using a dry etching method, a wet etching method, an ion implantation method, a metal plating method, or the like. Since the resist pattern is thickened, it can function as a mask even under severer conditions, and can be preferably used for processing by dry etching.

When processing the resist underlayer using the thickened film pattern, the processing can be performed step by step. For example, the thickened film pattern can be used to process an adhesion enhancing film and a SOC, and the SOC pattern can be used to process a substrate. For example, for the adhesion enhancing film, a SiARC (Si anti-reflective coating) can be used. An embodiment in which the substrate is directly processed using the thickened film pattern is a more preferable embodiment.

The method for manufacturing a device according to the present invention comprises the above-described method, and preferably further comprises a step of forming wiring on the processed substrate. For these processing, known methods can be applied. After that, if necessary, the substrate is cut into chips, connected to lead frames, and packaged with resin. In the present invention, this packaged product is called a device. The devices include semiconductor devices, liquid crystal display devices, organic EL display devices, plasma display devices, and solar cell devices. The device is preferably a semiconductor device.

### Example

The present invention is described below with reference to various examples. The embodiments of the present invention are not limited only to these examples.

### Preparation of Compositions of Examples 101 to 107

As shown in Table 1, each component is mixed in each compounding amount. First, the component (B1) and the component (B2) are mixed to obtain the solvent (B). The components (A), (D) and (F) are added to the solvent (B). The numerical values in Table 1 are the content (mass parts) of each component based on the total mass of the composition.

The resulting solution is stirred at room temperature for 30 minutes. After visually confirming that the solutes are completely dissolved, this solution is filtered through a 0.2 μm fluororesin filter to obtain the compositions of Examples 101 to 107.

TABLE 1

| | | | | | | | | | | | | | | Amount of |
|---|---|---|---|---|---|---|---|---|---|---|---|---|---|---|
| | | Component | | Component | | Component | | | | Component | | Component | | thickened |
| | | (A) | | (B1) | | (B2) | | | | (D) | | (F) | | film |
| Example | 101 | A1 | 0.245 | B1-1 | 93.000 | B2-1 | 0.245 | B2-2 | 6.495 | D1 | 0.010 | F1 | 0.005 | 6 nm |
| | 102 | A1 | 0.245 | B1-1 | 94.505 | B2-1 | 0.245 | B2-2 | 5.000 | — | — | F1 | 0.005 | 5 nm |
| | 103 | A1 | 0.245 | B1-1 | 99.510 | B2-1 | 0.245 | — | — | — | — | — | — | 5 nm |
| | 104 | A2 | 0.245 | B1-1 | 93.000 | B2-1 | 0.245 | B2-2 | 6.500 | D2 | 0.010 | — | — | 4 nm |
| | 105 | A3 | 0.245 | B1-1 | 93.000 | B2-1 | 0.245 | B2-2 | 6.500 | D3 | 0.010 | — | — | 4 nm |
| | 106 | A4 | 0.245 | B1-1 | 93.000 | B2-1 | 0.245 | B2-2 | 6.500 | D4 | 0.010 | — | — | 4 nm |
| | 107 | A5 | 0.245 | B1-1 | 93.000 | B2-1 | 0.245 | B2-2 | 6.500 | D5 | 0.010 | — | — | 4 nm |

The compounds listed in Table 1 are as follows.

A1 and A3 are shown below, and the protection rate of Y¹ (the ratio that Y¹ is the group represented by the formula (1) based on the total number of Y¹) is 78% and 50%, respectively.

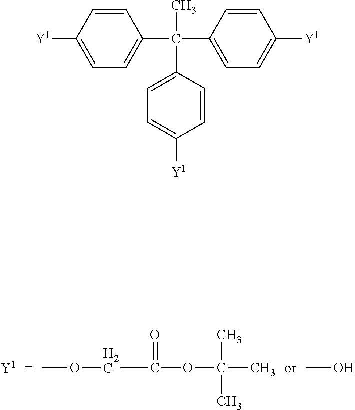

A2 is shown below, and the protection rate of Y² is 80%.

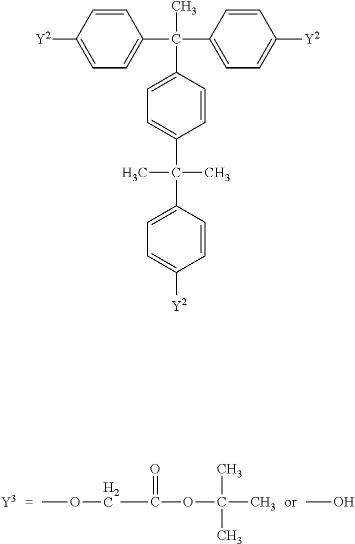

A4 is shown below, and the protection rate of Y³ is 49%.

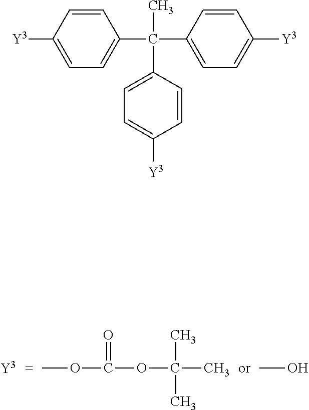

A5 is shown below, and the protection rate of Y⁴ is 78%.

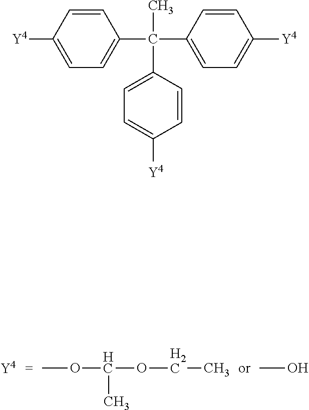

B1-1 is dibutyl ether.
B2-1 is PGMEA.
B2-2 is PGME.
D1 is triphenylsulfonium trifluoromethanesulfonate.
D2 is triphenylsulfonium trifluoroacetate.
D3 is triphenylsulfonium methanesulfonate.
D4 is triphenylsulfonium 4-methylbenzenesulfonate.
D5 is (4-methoxyphenyl)diphenylsulfonium trifluoro-methanesulfonate.
F1 is an acetylenic diol polyoxyalkylene ether having the following structure.

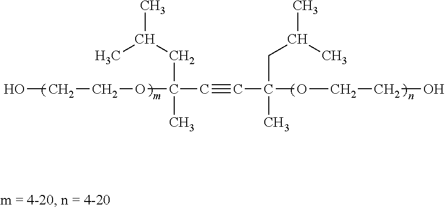

### Preparation of Compositions of Examples 201 to 206

As shown in Table 2, each component is mixed in each compounding amount. First, the component (B1) and the component (B2) are mixed to obtain the solvent (B). The components (A), (C), (D) and (F) are added to the solvent (B). The numerical values in Table 2 are the content (mass parts) of each component based on the total mass of the composition.

The resulting solution is stirred at room temperature for 30 minutes. After visually confirming that the solutes are completely dissolved, the solution is filtered through a 0.2 μm fluororesin filter to obtain compositions of Examples 201 to 206.

TABLE 2

| | | | | | | | | | | | | | | Amount of |
|---|---|---|---|---|---|---|---|---|---|---|---|---|---|---|
| | | Component | | Component | | Component | | Component | | Component | | Component | | thickened |
| | | (A) | | (B1) | | (B2) | | (C) | | (D) | | (F) | | film |
| Example | 201 | A6 | 0.125 | B1-1 | 99.750 | — | — | C1 | 0.125 | — | — | — | — | 5 nm |
| | 202 | A6 | 0.125 | B1-1 | 98.245 | B2-2 | 1.500 | C1 | 0.125 | — | — | F1 | 0.005 | 4 nm |
| | 203 | A6 | 0.125 | B1-1 | 93.235 | B2-2 | 6.500 | C1 | 0.125 | D1 | 0.010 | F1 | 0.005 | 4 nm |
| | 204 | A7 | 0.200 | B1-1 | 99.800 | — | — | — | — | — | — | — | — | 4 nm |
| | 205 | A8 | 0.150 | B1-1 | 99.725 | — | — | C1 | 0.125 | — | — | — | — | 4 nm |
| | 206 | A9 | 0.200 | B1-1 | 99.430 | B2-1 | 0.245 | C1 | 0.125 | — | — | — | — | 4 nm |

The compounds listed in Table 2 are as follows.
A6 is 1,4-butanediol divinyl ether.

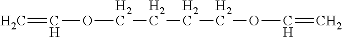

A7 is a copolymer shown below, and a polymer obtained by random polymerization of 1,4-butanediol divinyl ether (same as A6) and BIP—PC (same as C1) at a molar ratio of 1:2. Mw is 20,000 to 40,000.

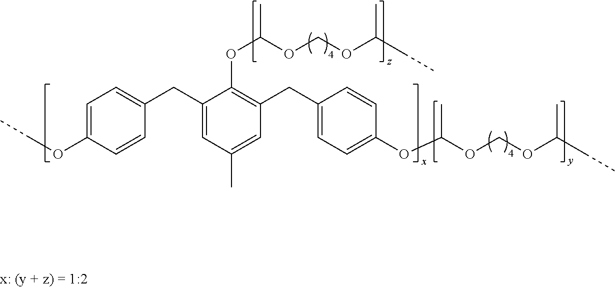

A8 is 1,4-cyclohexanedimethanol divinyl ether.

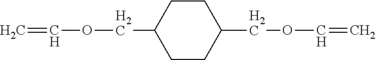

A9 is 1,3,5-tris [4-(ethenyloxy)butyl]1,3,5-cyclohexane-tricarboxylate (Toyo Gosei).

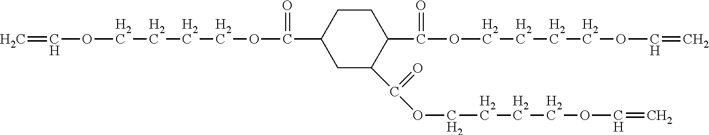 [SMILES: C=COCCCCOC(=O)C1CCC(C(=O)OCCCCOC=C)C(C(=O)OCCCCOC=C)C1]

C1 is BIP—PC (Asahi Yukizai) shown below.

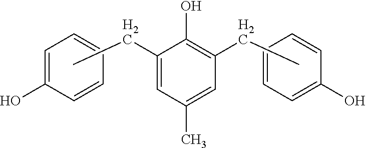

B1-1, B2-1, B2-2, D1 and F1 are the same as in Table 1.

### Preparation of Compositions of Examples 301 to 305

As shown in Table 3, each component is mixed in each compounding amount. First, the component (B1) and the component (B2) are mixed to obtain the solvent (B). The components (A), (D), and (F) are added to the solvent (B). The numerical values in Table 3 are the content (mass parts) of each component based on the total mass of the composition.

The resulting solution is stirred at room temperature for 30 minutes. After visually confirming that the solutes are completely dissolved, the solution is filtered through a 0.2 μm fluororesin filter to obtain compositions of Examples 301 to 305.

TABLE 3

| | | | | | | | | | | | | Amount of |
|---|---|---|---|---|---|---|---|---|---|---|---|---|
| | | Component | | Component | | Component | | Component | | Component | | thickened |
| | | (A) | | (B1) | | (B2) | | (D) | | (F) | | film |
| Example | 301 | A10 | 3.000 | B1-1 | 97.000 | — | — | — | — | — | — | 5 nm |
| | 302 | A10 | 3.000 | B1-1 | 92.000 | B2-2 | 5.000 | — | — | F1 | 0.005 | 5 nm |
| | 303 | A10 | 3.000 | B1-1 | 90.656 | B2-2 | 6.336 | D1 | 0.010 | — | — | 5 nm |
| | 304 | A11 | 2.000 | B1-1 | 98.000 | — | — | — | — | — | — | 5 nm |
| | 305 | A9 | 1.000 | B1-1 | 99.000 | — | — | — | — | — | — | 5 nm |

The compounds listed in Table 3 are as follows.
A10 is cyclohexyl vinyl ether.

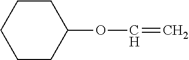

A11 is 1,4-cyclohexanedimethanol divinyl ether.

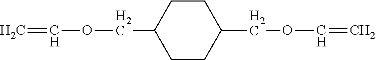

A9, B1-1, B2-2, D1 and F1 are the same as in Tables 1 and 2.

### Manufacturing of a Resist Overlayer Pattern and a Resist Pattern

A silicon substrate is subjected to HMDS (hexamethyldisilazane) treatment at 90° C. for 30 seconds. A chemically amplified PHS-acrylate hybrid resist composition is applied on the HMDS-treated substrate by spin coating and heated with a hot plate at 110° C. for 60 seconds to form a resist film with a film thickness of 35 nm. Using an EUV exposure apparatus (NXE: 3300B, ASML), the resist layer is exposed through a mask having a size of 18 nm (line:space=1:1) while changing the exposure dose. After that, PEB is performed at 100° C. for 60 seconds. Thereafter, the composition of the above Example is applied onto the resist film by spin coating and heated at 90° C. for 60 seconds to form a resist overlayer. Thereafter, puddle development is performed for 30 seconds using a 2.38 mass % TMAH aqueous solution as a developer, water is started to be dropped in a state that the developer is puddled on the substrate, and water continues to be dropped while rotating the substrate, thereby replacing the developer with water. Thereafter, the substrate is rotated at high speed to dry the thickened resist pattern (the resist overlayer pattern and the resist pattern).

For comparison, a resist pattern to which any composition of Example is not applied is formed. In particular, a resist pattern is formed in the same manner as described above, except that the composition of Example is not applied and the subsequent heating is not performed. This is called a comparative resist pattern.

### Evaluation of Amount of Thickened Film

Slices of the substrate are prepared for each of the thickened resist pattern and the comparative resist pattern, and the cross-sectional shapes are observed with an SEM (SU8230, Hitachi High-Tech Fielding) to measure the height of the pattern. (Film thickness of the resist pattern+film thickness of the resist overlayer pattern)−(film thickness of the comparative resist pattern) is calculated as the amount of thickened film. The results obtained are listed in Tables 1 to 3.

### EXPLANATION OF SYMBOLS

1. substrate
2. resist film
3. exposed area
4. unexposed area
5. resist overlayer
6. resist pattern
7. resist overlayer pattern

1. A developable resist overlayer composition comprising a hydrocarbon compound (A) and a solvent (B),
wherein,
the hydrocarbon compound (A) is a compound represented by the formula (0) or a polymer comprising a structure derived from the compound represented by the formula (0) as a repeating unit; and
the solvent (B) comprises a solvent (B1) represented by the formula (b1): 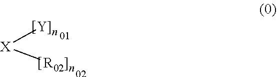
wherein
X is a C₁₋₆₀ hydrocarbon group;
n₀₁ is a number of 1 to 10, n₀₂ is a number of 0 to 10;
Y is a group represented by the formula (1) or —OH, provided that 40 to 100% of the total number of Y is a group represented by the formula (1);
R₀₂ is C₁₋₆ alkoxy (excluding t-butoxy), —(C═O)—R₀₃, —(C═O)—O—
R₀₄, —(C═O)—N(R₀₅)₂, —O—(C═O)—R₀₆ or —NR₀₇—(C═O)—R₀₈;
R₀₅ is H or C₁₋₄ alkyl;
R₀₄ is C₁₋₄ alkyl (excluding t-butyl);
R₀₆ is each independently H or C₁₋₄ alkyl, and two R₀₅ can be bonded each other to form a ring structure;
R₀₆ is H, C₁₋₄ alkyl or C₁₋₄ alkoxy (excluding t-butoxy);
R₀₇ is H or C₁₋₄ alkyl;
R₀₈ is H, C₁₋₄ alkyl or —N(R₀₉)₂;
R₀₇ and R₀₈ can be bonded each other to form a ring structure when they are alkyl; and
R₀₉ is each independently H or C₁₋₄ alkyl, and two R₀₉ can be bonded each other to form a ring structure, 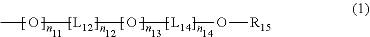
wherein
n₁₁, n₁₂, n₁₃ and n₁₄ are each independently a number of 0 to 1;
L₁₂ is selected from the group consisting of —C(═O)—, —CH₂—C(═O)—, —C(═O)—CH₂— and —CH(CH₃)—;
L₁₄ is C₁₋₅ alkylene;
R₁₅ is C₁₋₁₅ alkyl or C₂₋₇ alkenyl; and
the methyl of L₁₂ and the methyl of R₁₅ may be bonded each other to form a ring structure, and
R₂₁—O—R₂₂ (b1)
wherein
R₂₁ and R₂₂ are each independently C₁₋₈ alkyl.

2. The composition according to claim 1, wherein X is represented by formula (X-1) or formula (X-2): 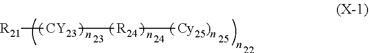
wherein
R₂₁ and R₂₄ are each independently a linear or branched C₁₋₁₀ aliphatic hydrocarbon group;
n₂₂ is a number of 0 to 5;
Cy₂₃ and Cy₂₅ are each independently a cyclic hydrocarbon group having a C₅-10 ring atom;
n₂₃ is each independently a number of 0 to 1; and
n₂₄ and n₂₅ are each independently a number of 0 to 3, 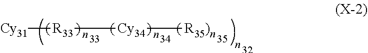
wherein
Cy₃₁ and Cy₃₄ are each independently a cyclic hydrocarbon group having a C₅-10 ring atom;
n₃₂ is a number of 0 to 5;
R₃₃ is each independently linear or branched C₁₋₁₀ alkyl;
R₃₅ is each independently linear or branched C₁₋₁₀ alkyl;
n₃₃ is each independently a number of 0 to 1;
n₃₄ and n₃₅ are each independently a number of 0 to 3.

3. The composition according to claim 1, further comprising a hydroxy-containing compound (C) represented by the formula (c): 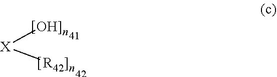
wherein
R₄₂ is C₁₋₆ alkoxy, —(C═O)—R₀₃, —(C═O)—O—R₀₄, —(C═O)—N(R₀₅)₂, —O—(C=O)—R₀₆ or —NR₀₇—(C═O)—R₀₈; and
n₄₁ is a number of 1 to 10, and n₄₂ is a number of 0 to 10.

4. The composition according to claim 1, wherein the solvent (B) further comprises a solvent (B2) selected from the group consisting of cyclohexanone, cyclopentanone, propylene glycol monomethyl ether, propylene glycol monoethyl ether, propylene glycol monopropyl ether, propylene glycol monobutyl ether, propylene glycol dimethyl ether, propylene glycol diethyl ether, propylene glycol monomethyl ether acetate, propylene glycol monoethyl ether acetate, propylene glycol monopropyl ether acetate, γ-butyrolactone, ethyl lactate, and any combination thereof.

5. The composition according to claim 1, further comprising an acid generator (D), which releases an acid with an acid dissociation constant pKa(H₂O) of −14 to 8 by reaction with an acid, the content of the acid generator (D) being 0.01 to 40 mass % based on the hydrocarbon compound (A).

6. The composition according to claim 1, which is substantially free of a photo-strong acid generator (E),
wherein,
the photo-strong acid generator (E) releases an acid with an acid dissociation constant pKa(H₂O) of −20 to 1.4 by exposure; and
the content of the photo-strong acid generator (E) is 0 to 1.00 mass % based on the hydrocarbon compound (A).

7. The composition according to claim 1, further comprising a surfactant (F) at a concentration of 0 to 10 mass % based on the hydrocarbon compound (A).

8. The composition according to claim 1, further comprising an additive (G) selected from the group consisting of a surface smoothing agent, an acid, a base, a substrate adhesion enhancer, an antifoaming agent, and any combination thereof.

9. The composition according to claim 4, wherein at least one of the following is satisfied:
the content of the hydrocarbon compound (A) is 0.01 to 15 mass % based on the composition,
the content of the solvent (B) is 70 to 99.99 mass % based on the composition;
the content of the solvent (B1) is 70 to 100 mass % based on the solvent (B), or
the content of the solvent (B2) is 0 to 30 mass % based on the solvent (B).

10. The composition according to claim 1, which is a developable resist overlayer composition to be formed on a resist film after exposure.

11. A method for manufacturing a resist overlayer pattern and a resist pattern comprising:
(1) applying a resist composition above a substrate and heating the resist composition to form a resist film;
(2) optionally exposing the resist film;
(3) applying a developable resist overlayer composition directly on the resist film and heating the resist overlayer composition to form a resist overlayer;
(4) optionally exposing the resist film and the resist overlayer, provided that at least one of the exposures of (2) and (4) is performed;
(5) transferring the acid in the resist film to the resist overlayer; and
(6) developing the resist overlayer and the resist film using a developer to form a resist overlayer pattern and a resist pattern, wherein the step (2) is optionally followed by a step (2-2) of heating the step (4) is optionally followed by a step (4-2) of heating.

12. The method according to claim 11, wherein the developable resist overlayer composition is the composition according to claim 1.

13. The method according to claim 11, wherein the thickness of the resist overlayer to be formed in the step (3) is 1 to 10 nm.

14. The method according to claim 11, wherein the solubility of the resist overlayer to the developer changes by the acid transferred in the step (5), and wherein the acid generated from the photo-strong acid generator (E) in the resist film is ion-exchanged with the acid generator (D) in the resist overlayer, and wherein the acid derived from the acid generator (D) diffuses into the resist overlayer, and the solubility of the resist overlayer to the developer changes.

15. The method according to claim 11, wherein in the step (3), the hydrocarbon compound (A) in the developable resist overlayer composition is bonded to the resist film to become insoluble to the developer, and
the resist overlayer becomes soluble to the developer by the acid transferred in the step (5).

16. The method according to claim 11, further comprising the following step (7):
(7) washing the resist overlayer pattern and the resist pattern with a cleaning liquid and removing the cleaning liquid from between the patterns.

17. A method for manufacturing a processed substrate comprising:
forming a resist overlayer pattern and a resist pattern by the method according to claim 11; and
(8) processing using the resist overlayer pattern and the resist pattern as a mask.

18. A method for manufacturing a device comprising the method according to claim 11, further comprising a step of forming wiring on the processed substrate.
